(19) United States
(12) Patent Application Publication
(10) Pub. No.: US 2017/0373587 A1
(43) Pub. Date: Dec. 28, 2017

(54) COMPACT PARTITIONED CAPACITOR FOR MULTIPLE VOLTAGE DOMAINS WITH IMPROVED DECOUPLING

(71) Applicant: Intel Corporation, Santa Clara, CA (US)

(72) Inventors: Chin Lee Kuan, Bayan Lepas (MY); Sameer Shekhar, Portland, OR (US); Amit K. Jain, Portland, OR (US)

(73) Assignee: Intel Corporation, Santa Clara, CA (US)

(21) Appl. No.: 15/195,671

(22) Filed: Jun. 28, 2016

(51) Int. Cl. H02M 1/14; H05K 1/18; H05K 1/02; H02M 1/00

(52) U.S. Cl. CPC H02M 1/14; H05K 1/0231; H05K 1/181; H05K 2201/1003; H02M 2001/009; H05K 2201/10159; H05K 2201/10515; H05K 2201/10015

(57) ABSTRACT

Methods and apparatus relating to a compact partitioned capacitor design for multiple voltage and/or load domains (e.g., with improved decoupling) are described. In an embodiment, a capacitor provides substrate decoupling for a plurality of loads. Moreover, the capacitor is capable of decoupling two or more voltage domains. Furthermore, in some embodiments the capacitor is capable of decoupling two or more voltage domains and mitigating self-noise and/or cross-noise between them. Other embodiments are also disclosed and claimed.

### FIELD

The present disclosure generally relates to the field of electronics. More particularly, some embodiments relate to a compact partitioned capacitor for multiple voltage and/or load domains.

### BACKGROUND

Generally, power delivery noise suppression relies on semiconductor substrate decoupling in the form of discrete capacitors. The capacitor choice can be made through independent analyses for each load. However, the total capacitance is limited by available space, which shrinks with semiconductor process and increased integration.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIGS. 1, 8, 9, and 10 illustrate block diagrams of embodiments of computing systems, which may be utilized to implement various embodiments discussed herein.

FIGS. 2, 6, 7A, and 7B illustrate capacitance structures, according to some embodiments.

FIGS. 3 and 5A illustrate various semiconductor footprints, according to some embodiments.

FIGS. 4 and 5B illustrate sample graphs according to some embodiments.

### DETAILED DESCRIPTION

In the following description, numerous specific details are set forth in order to provide a thorough understanding of various embodiments. However, various embodiments may be practiced without the specific details. In other instances, well-known methods, procedures, components, and circuits have not been described in detail so as not to obscure the particular embodiments. Further, various aspects of embodiments may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

As mentioned above, the total capacitance for semiconductor package decoupling is limited by available space. As discussed herein, package decoupling may include decoupling of one or more substrates of a semiconductor package. Moreover, package decoupling technology is not currently scaling adequately with Silicon process and reduced area needs for emerging compute devices and platforms. This leads to higher voltage noise at load points. Also, product feature set enhancement and/or battery life concerns may need stringent power consumption restrictions, e.g., which may be met by voltage rail count increase for power savings or noise. Even if size is compromised by increasing area devoted to capacitors, the effectiveness of such decoupling can be limited. In addition, due to close proximity of noise sensitive IPs (Intellectual Property blocks), it is becoming very difficult to have adequate independent decoupling. Also, some solutions may include higher die capacitance, package layer addition, and/or cavity size increase to add more decoupling capacitors with the penalty of cost and/or form factor increase.

To this end, some embodiments provide a compact partitioned capacitor design for multiple voltage and/or load domains, e.g., with improved decoupling. An embodiment provides a single capacitor to support two or more power rails (also referred to herein as power or voltage domains) in three or higher terminal configuration to obviate a need for SRO (Solder Resist Opening) spacing required for independent decoupling. This results in higher capacitance and/or lower parasitic inductance on the package substrate and/or motherboard. With increased integration and further process shrink, these structures may be the only way to have decoupling for multiple IPs (or Intellectual Property blocks) in a small area. Such capacitor design may be used to provide a decoupling solution for two or more voltage domains, e.g., by reassigning/splitting metallization plates inside a Multilayer Ceramic Capacitor (MLCC) construction.

Moreover, one or more embodiments discussed herein can provide better utilization (e.g., about 30%) of available substrate area at no cost increase and/or better package connection of the proposed capacitor (e.g., due to closer proximity to loads). Furthermore, such techniques may save about 30% of decoupling area and/or provide up to about 30% load line reduction for some products. Hence, some embodiments help scale discrete decoupling with process shrink and/or reduce form-factor of computing platforms.

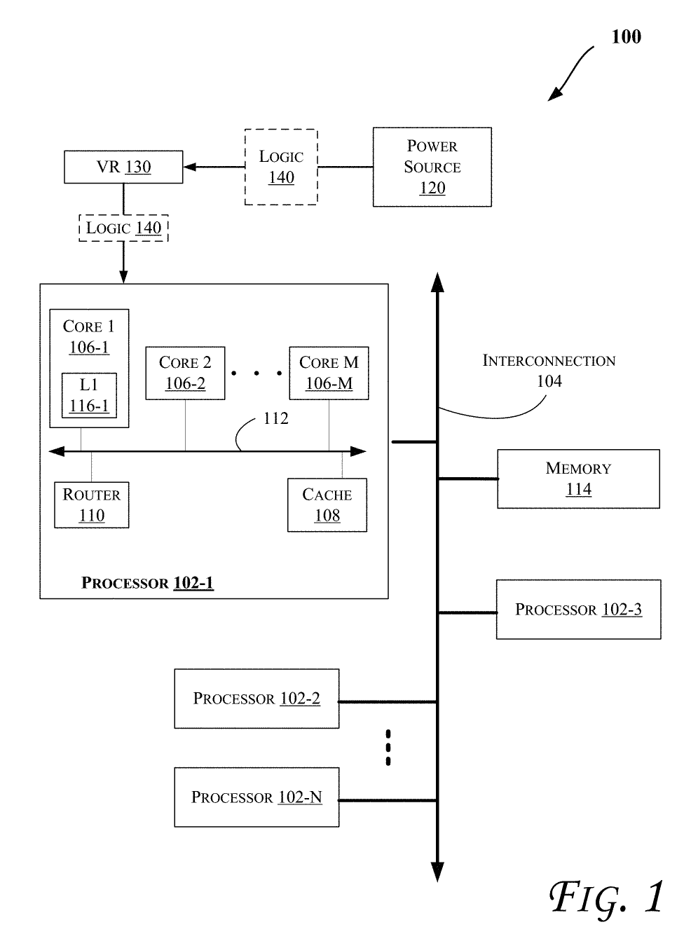

Additionally, some embodiments may be applied in computing systems that include one or more processors (e.g., with one or more processor cores), such as those discussed with reference to FIGS. 1-10, including for example mobile computing devices (and/or platforms) such as a smartphone, tablet, UMPC (Ultra-Mobile Personal Computer), laptop computer, Ultrabook™ computing device, smart watch, smart glasses, wearable devices, etc., and/or larger systems such as computer servers with many cores, etc. More particularly, FIG. 1 illustrates a block diagram of a computing system 100, according to an embodiment. The system 100 may include one or more processors 102-1 through 102-N (generally referred to herein as “processors 102” or “processor 102”). The processors 102 may communicate via an interconnection or bus 104. Each processor may include various components some of which are only discussed with reference to processor 102-1 for clarity. Accordingly, each of the remaining processors 102-2 through 102-N may include the same or similar components discussed with reference to the processor 102-1.

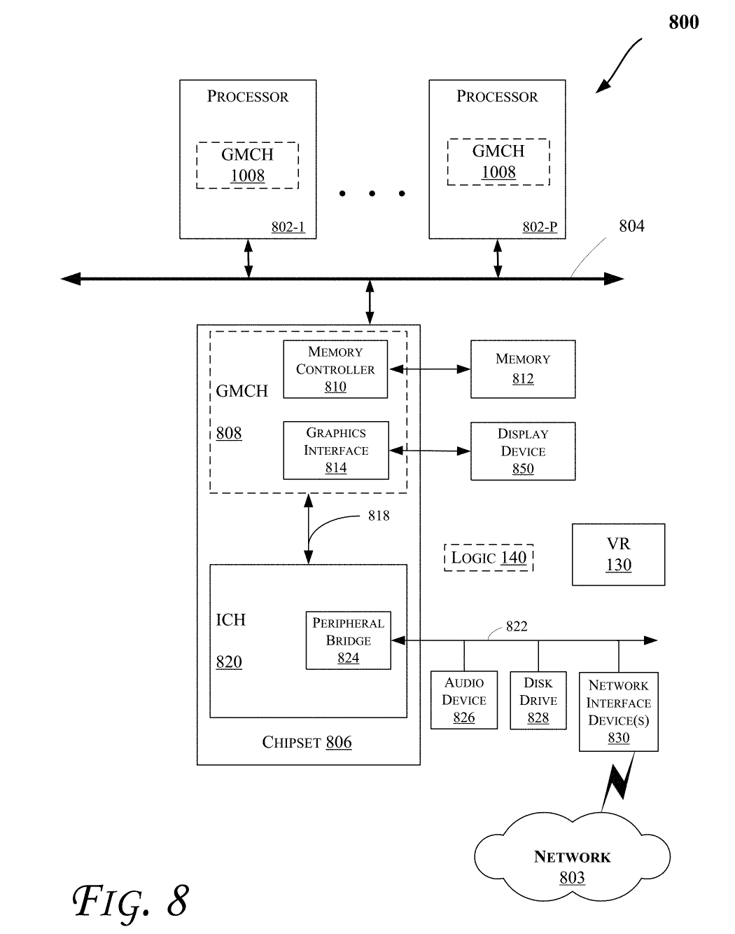

In an embodiment, the processor 102-1 may include one or more processor cores 106-1 through 106-M (referred to herein as “cores 106,” or “core 106”), a cache 108, and/or a router 110. The processor cores 106 may be implemented on a single integrated circuit (IC) chip. Moreover, the chip may include one or more shared and/or private caches (such as cache 108), buses or interconnections (such as a bus or interconnection 112), graphics and/or memory controllers (such as those discussed with reference to FIGS. 8-10), or other components.

In one embodiment, the router 110 may be used to communicate between various components of the processor 102-1 and/or system 100. Moreover, the processor 102-1 may include more than one router 110. Furthermore, the multitude of routers 110 may be in communication to enable data routing between various components inside or outside of the processor 102-1.

The cache 108 may store data (e.g., including instructions) that are utilized by one or more components of the processor 102-1, such as the cores 106. For example, the cache 108 may locally cache data stored in a memory 114 for faster access by the components of the processor 102 (e.g., faster access by cores 106). As shown in FIG. 1, the memory 114 may communicate with the processors 102 via the interconnection 104. In an embodiment, the cache 108 (that may be shared) may be a mid-level cache (MLC), a last level cache (LLC), etc. Also, each of the cores 106 may include a level 1 (L1) cache (116-1) (generally referred to herein as “L1 cache 116”) or other levels of cache such as a level 2 (L2) cache. Moreover, various components of the processor 102-1 may communicate with the cache 108 directly, through a bus (e.g., the bus 112), and/or a memory controller or hub.

The system 100 may also include a platform power source 120 (e.g., a Direct Current (DC) power source or an Alternating Current (AC) power source) to provide power to one or more components of the system 100. The power source 120 could include a PV (Photo Voltaic) panel, wind generator, thermal generator water/hydro turbine, etc. In some embodiments, the power source 120 may include one or more battery packs (e.g., charged by one or more of a PV panel, wind generator, thermal generator water/hydro turbine, plug-in power supply (for example, coupled to an AC power grid), etc.) and/or plug-in power supplies. The power source 120 may be coupled to components of system 100 through a Voltage Regulator (VR) 130. Moreover, even though FIG. 1 illustrates one power source 120 and a single voltage regulator 130, additional power sources and/or voltage regulators may be utilized. For example, one or more of the processors 102 may have corresponding voltage regulator(s) and/or power source(s). Also, the voltage regulator(s) 130 may be coupled to the processor 102 (and/or cores 106) via a single power plane (e.g., supplying power to all the cores 106) or multiple power planes (e.g., where each power plane may supply power to a different core or group of cores).

As discussed herein, various type of voltage regulators may be utilized for the VR 130. For example, VR 130 may include a “buck” VR (which is generally used in power delivery applications in which an input voltage needs to be transformed to an output voltage in a ratio that is smaller than unity) or a “boost” VR (which is generally used in power delivery applications in which an input voltage needs to be transformed to an output voltage in a ratio that is larger than unity), combinations thereof such as a buck-boost VR, etc. Furthermore, in an embodiment, a dual phase, e.g., that may be extendable to multi-phase three-Level buck VR topology.

Additionally, while FIG. 1 illustrates the power source 120 and the voltage regulator 130 as separate components, the power source 120 and the voltage regulator 130 may be incorporated into other components of system 100. For example, all or portions of the VR 130 may be incorporated into the power source 120 and/or processor 102.

As shown in FIG. 1, system 100 may further include logic 140 to provide a compact partitioned capacitor for multiple voltage domains with improved decoupling, e.g., as discussed herein with reference to some embodiments. In an embodiment, logic 140 is provided on a reconfigurable power management ICs (RPMICs), such as a PMIC (Power Management IC) and/or an IMVP (Intel® Mobile Voltage Positioning). Such RPMIC implementation(s) may be used in low power devices (such as portable devices discussed herein) through large computer servers such as discussed herein with reference to FIG. 1 or 8-10.

Also, as shown, the logic 140 may be coupled to the VR 130 and/or other components of system 100 such as the processor 102 (and/or cores 106) and/or the power source 120. Also, logic 140 may be provided elsewhere in system 100, such as inside the VR 130, inside the processor 102, inside the power source 120, etc.

Moreover, processor die size and bump pitch have been shrinking over generations in accordance with Moore's Law. Furthermore, circuit blocks introduced to enhance feature sets, tighter power management, and/or noise mitigation have led to power rail proliferation and consequent higher capacitor decoupling requirement per unit area. For example, the DDR (Double Data Rate) interface on some processor may have needed four supplies in shrinking area. Hence, this would need one capacitor per DDR byte for two of the supplies, which is something infeasible on some packages with current capacitors and associated design rules. This may be due to a reduction in DDR circuit dimension going from one process node to another, for example. As a result, overall capacitor count allocation for entire memory span can be lower.

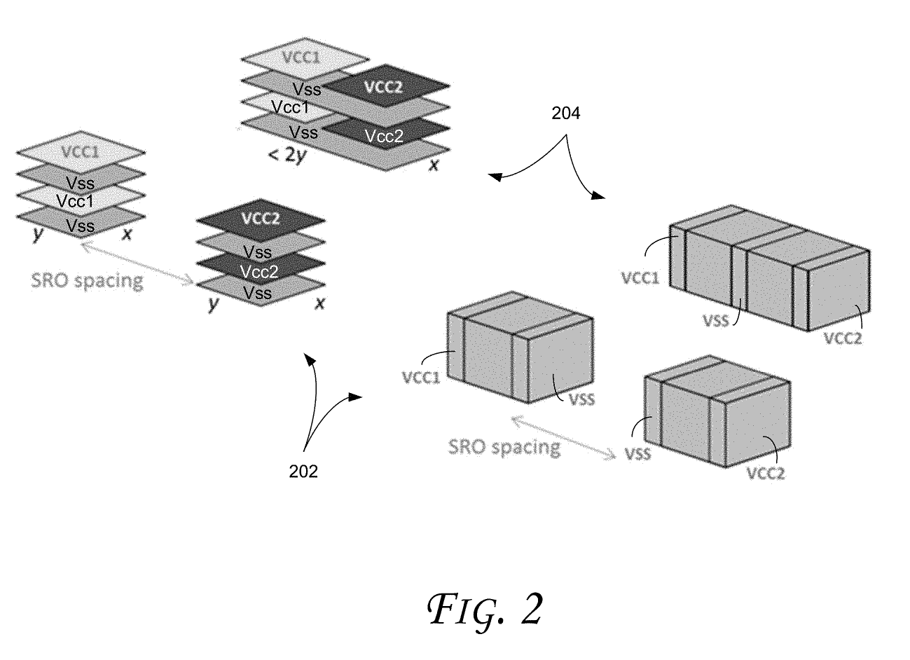

FIG. 2 illustrates a block diagram of a two rail three terminal (3T) capacitor structure versus two terminal (2T) capacitors, according to an embodiment. The structures in FIG. 2 utilize significantly less footprint area as compared to existing solutions due to elimination of SRO (Solder Resist Opening) spacing and double use of the return path pad. One implementation may utilize existing 3T capacitor manufacturing technology with modified termination to support two independent power rails and a common ground. ESR (Equivalent Series Resistance) and ESL (Equivalent Series Inductance) is expected to be better or the same as a discrete capacitor due to the two parallel paths available for the return current (e.g., one benefit of the 3T structure).

Combinations of 2T capacitors (202) use an extra length for SRO spacing due to SRO spacing constraints. An embodiment with a 3T capacitor (204) can provide double the capacitance value with reduced form factor due to SRO spacing elimination (when compared with two 2T capacitors 202). Moreover, one or more of the following may be provided by the structure 204: about 27% (or more) package or board area saving while maintaining similar performance levels; about 35% enhancement of capacitance per unit area; and/or about 30% higher performance (in terms of impedance reduction).

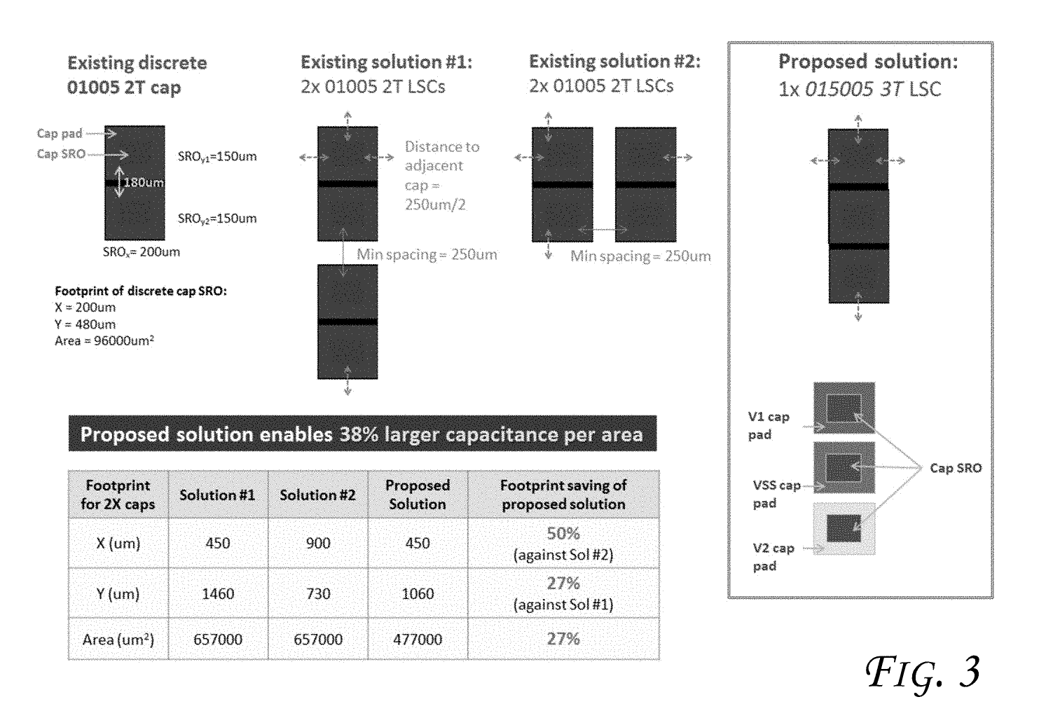

Generally, SRO spacing is needed to reliably place two adjacent capacitors and prevent short circuits due to solder bridges between closely spaced solder pads. This restricts effective capacitor count per unit area, especially for small form factor capacitors. For example, some designs (such as shown in FIG. 3 which illustrates area for various solutions versus some embodiments) may apply minimum component spacing rule between SRO of two adjacent capacitors. With proposed three terminal capacitor, at least 33% board or package area saving can be realized. Area saving is significant for limited design space as more number of circuits co-exist for a given or shrinking die area.

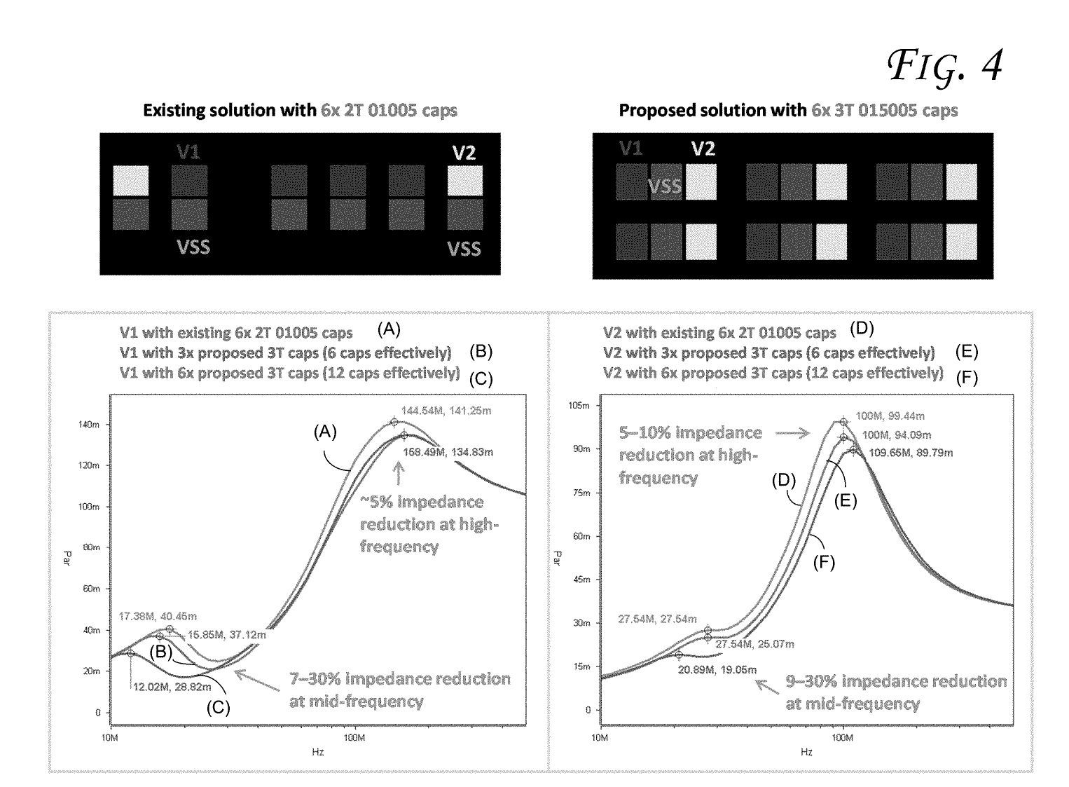

FIG. 4 illustrates potential load line improvements in accordance with some embodiments. For example, FIG. 4 shows sample simulation results done on V1 and V2, corresponding to two voltage domains that may co-exist on a CPU. With about 30% less area, proposed solutions can also provide performance benefit over existing solution. Also, if instead of needing twice the area, capacitor value is doubled with about 50% space increase, solution can provide 30% performance improvement on mid-frequency noise.

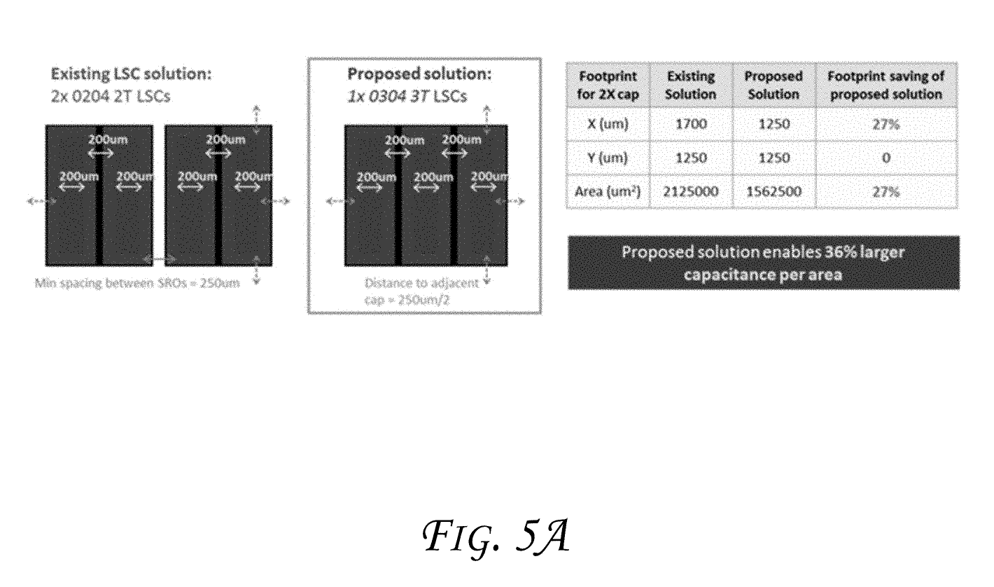

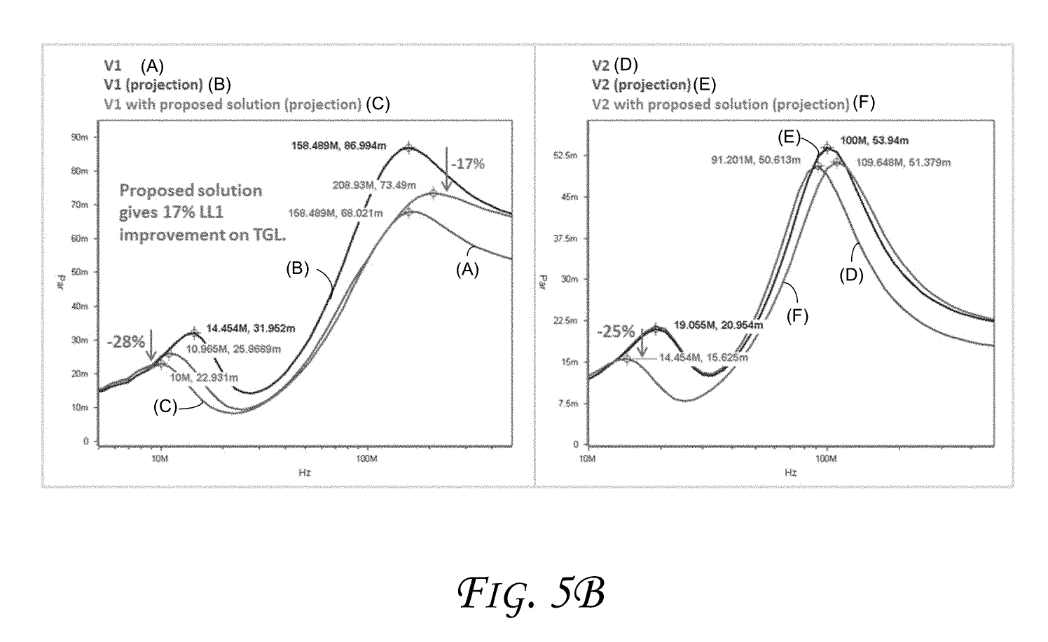

In an embodiment, similar techniques could also be applied on larger (e.g., 0204 and 0402) capacitors for mid-frequency noise reduction such as shown in FIG. 5A. For example, V2 and VCC3 (System Agent Voltage) on some products may both use 0204 capacitors and be placed in close proximity. As illustrated in FIG. 5A, at least one embodiment allows about 27% area saving with 36% larger capacitance per unit area. By taking advantage of reduced SRO, such an embodiment could bring larger capacitance values and address decoupling for higher number of domains in a small area.

Moreover, performance gain may be higher on products with die shrink. FIG. 5B shows performance improvement projection for die size reduction of 25%, according to an embodiment. As shown, there can be about 25% mid-frequency and about 17% high-frequency impedance reduction on the interface. This may eliminate mid-frequency noise concerns and alleviates the high-frequency risks. Furthermore, one or more embodiments may improve motherboard capacitors, memory modules, and/or other chip package design, such as SoCs (System on Chips) and/or PCH (Peripheral Control Hub), e.g., where limited package cavity is available to attach passive components. Additionally, one or more embodiments can be used by both the component manufacturers on the package or module substrate, and/or by the ODM/OEM (Original Design Manufacturer/Original Equipment Manufacturer) on the motherboard.

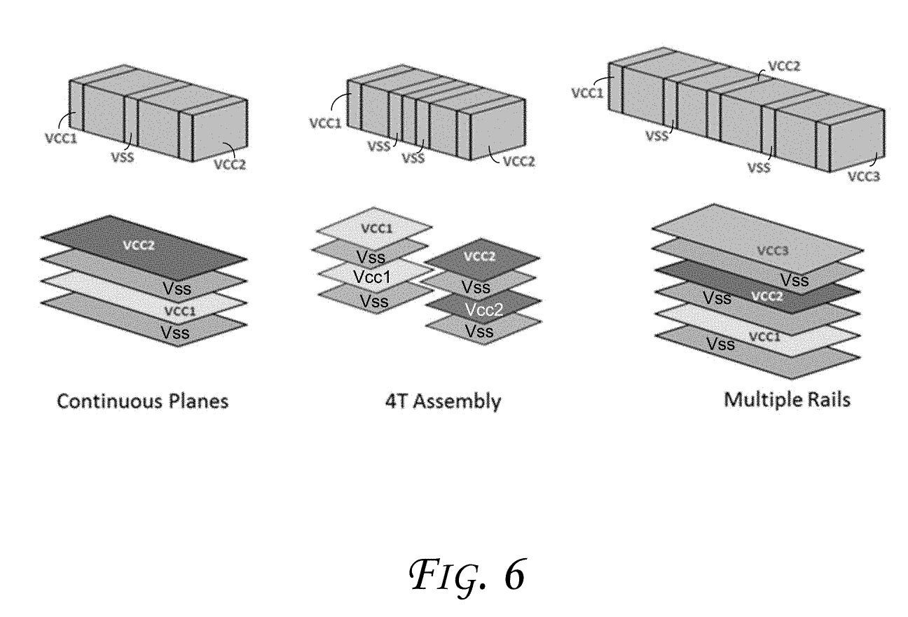

FIG. 6 illustrates different geometries according to various embodiments. More particularly, some other possible geometries for the proposed structure are shown in FIG. 6. Other structures can be derived by combining variations of the ideas of split planes and multiple terminals to accommodate required number of rails, including the illustrated continuous planes, 4T assembly, and multiple rails.

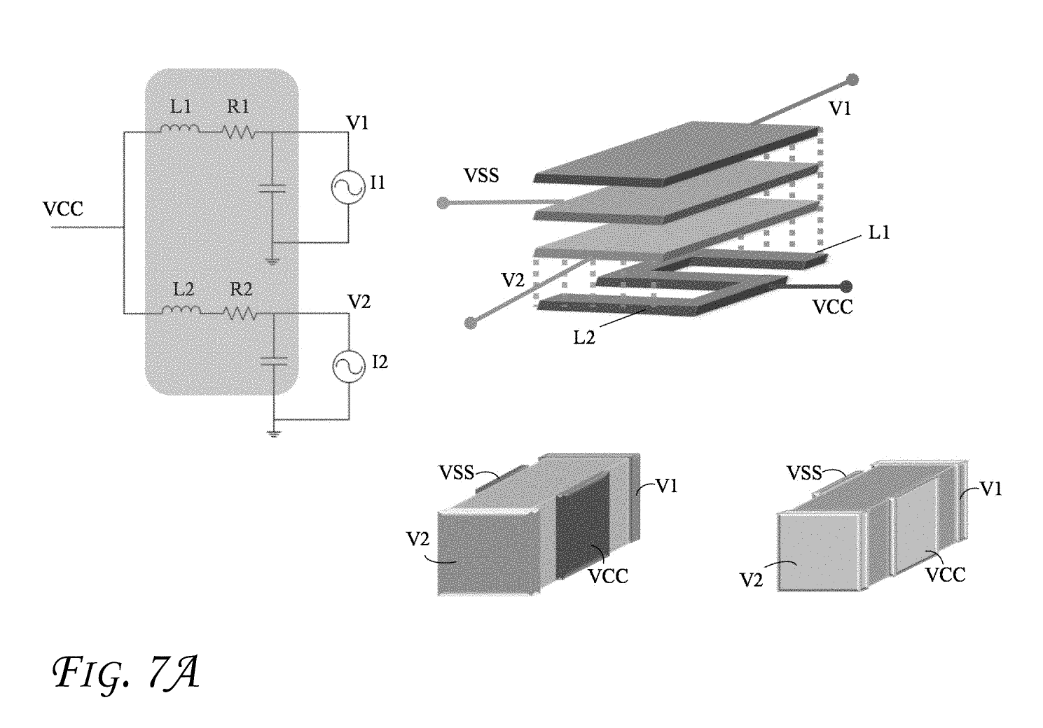

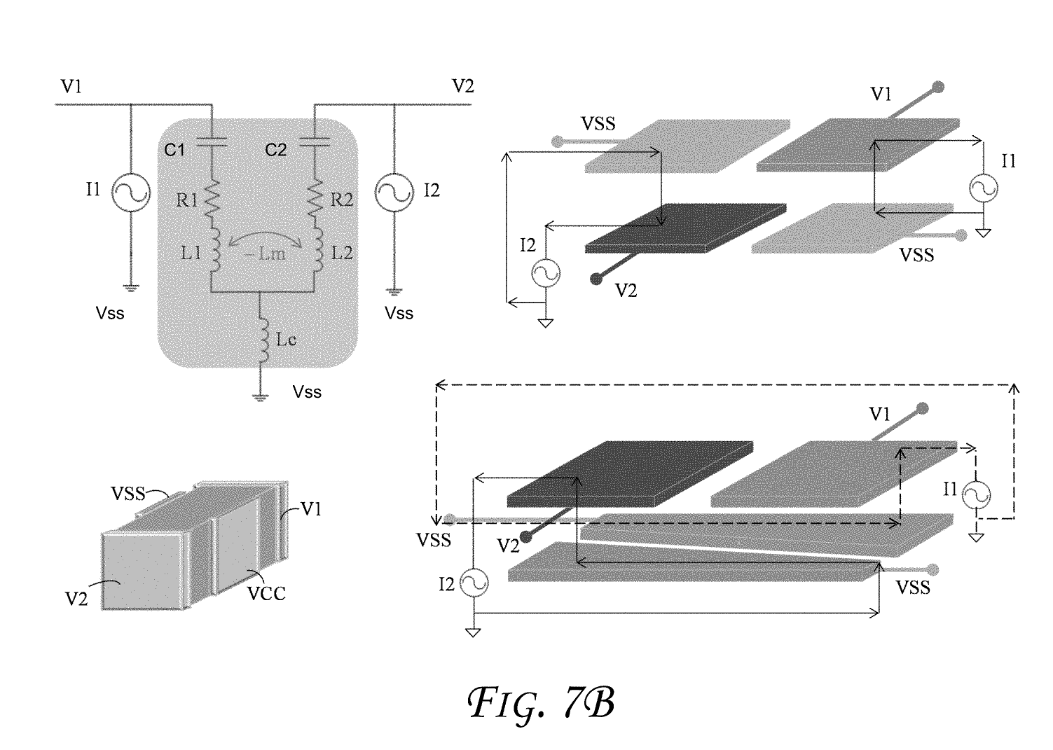

FIGS. 7A and 7B illustrate physical assemblies for decoupling capacitors as well as their corresponding equivalent circuits, according to some embodiments. More specifically, FIG. 7A shows a physical assembly incorporating two decoupling capacitors (C1 and C2) with designed inductive isolation (L1 and L2) for lower cross-coupling noise between two different loads (I1 and I2) having the same nominal voltage (Vcc). The inclusion of inductive structures in the capacitor further reduces space required for implementing them with physically drawn features or as discrete inductors.

FIG. 7B shows a physical assembly incorporating two decoupling capacitors (C1 and C2) having the same or different DC (Direct Current) voltage (V1 and V2) with or without negative coupling (−Lm) between series inductors for lower cross-noise and self-noise between two different loads. Two embodiments of negative coupling between the two loads are shown in FIG. 7B. In the top picture, electrode plate connections are swapped so current directions (arrows) are opposite between V1 and V2; thus, providing negative coupling via magnetic field in the space between the electrodes. In the bottom picture, the return current electrodes (VSS) are shaped such that currents in the bottom plate for the two loads produce magnetic flux in opposite directions. Both FIGS. 7A and 7B show equivalent circuits on the left upper portion of the figures, having two loads (labeled as I1 and I2), two resistors (labeled R1 and R2), two capacitors (C1 and C2), and two inductors (labeled L1 and L2).

Accordingly, one or more embodiments can provide one or more of the following: (a) use of proposed capacitors for decoupling can lead to about 30% package/board area saving and about 10-30% impedance reduction; (b) reduction of capacitor area on IC packages can reduce package form factor and cost; (c) application to multiple loads decoupling as discussed herein; (d) application to multiple loads supplied from same voltage regulator can reduce cross-noise and capacitor area on package or board (e) application to loads on different voltages can reduce total noise and capacitor area on package or board.

FIG. 8 illustrates a block diagram of a computing system 800 in accordance with an embodiment. The computing system 800 may include one or more central processing unit(s) (CPUs) or processors 802-1 through 802-P (which may be referred to herein as “processors 802” or “processor 802”). The processors 802 may communicate via an interconnection network (or bus) 804. The processors 802 may include a general purpose processor, a network processor (that processes data communicated over a computer network 803), or other types of a processor (including a reduced instruction set computer (RISC) processor or a complex instruction set computer (CISC)). Moreover, the processors 802 may have a single or multiple core design. The processors 802 with a multiple core design may integrate different types of processor cores on the same integrated circuit (IC) die. Also, the processors 802 with a multiple core design may be implemented as symmetrical or asymmetrical multiprocessors. In an embodiment, one or more of the processors 802 may be the same or similar to the processors 102 of FIG. 1. In some embodiments, one or more of the processors 802 may include one or more of the cores 106, VR 130, and/or logic 140 of FIG. 1. Also, the operations discussed with reference to FIGS. 1-7 may be performed by one or more components of the system 800. For example, a voltage regulator (such as VR 130 of FIG. 1) may regulate voltage supplied to one or more components of FIG. 8 in conjunction with logic 140.

A chipset 806 may also communicate with the interconnection network 804. The chipset 806 may include a graphics and memory control hub (GMCH) 808. The GMCH 808 may include a memory controller 810 that communicates with a memory 812. The memory 812 may store data, including sequences of instructions that are executed by the processor 802, or any other device included in the computing system 800. In one embodiment, the memory 812 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 804, such as multiple CPUs and/or multiple system memories.

The GMCH 808 may also include a graphics interface 814 that communicates with a display device 850, e.g., a graphics accelerator. In one embodiment, the graphics interface 814 may communicate with the display device 850 via an accelerated graphics port (AGP) or Peripheral Component Interconnect (PCI) (or PCI express (PCIe) interface). In an embodiment, the display device 850 (such as a flat panel display (such as an LCD (Liquid Crystal Display), a cathode ray tube (CRT), a projection screen, etc.) may communicate with the graphics interface 814 through, for example, a signal converter that translates a digital representation of an image stored in a storage device such as video memory or system memory into display signals that are interpreted and displayed by the display. The display signals produced may pass through various control devices before being interpreted by and subsequently displayed on the display device 850.

A hub interface 818 may allow the GMCH 808 and an input/output control hub (ICH) 820 to communicate. The ICH 820 may provide an interface to I/O devices that communicate with the computing system 800. The ICH 820 may communicate with a bus 822 through a peripheral bridge (or controller) 824, such as a peripheral component interconnect (PCI) bridge, a universal serial bus (USB) controller, or other types of peripheral bridges or controllers. The bridge 824 may provide a data path between the processor 802 and peripheral devices. Other types of topologies may be utilized. Also, multiple buses may communicate with the ICH 820, e.g., through multiple bridges or controllers. Moreover, other peripherals in communication with the ICH 820 may include, in various embodiments, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 822 may communicate with an audio device 826, one or more disk drive(s) 828, and one or more network interface device(s) 830 (which is in communication with the computer network 803). Other devices may communicate via the bus 822. Also, various components (such as the network interface device 830) may communicate with the GMCH 808 in some embodiments. In addition, the processor 802 and the GMCH 808 may be combined to form a single chip. Furthermore, the graphics accelerator may be included within the GMCH 808 in other embodiments.

Furthermore, the computing system 800 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 828), a floppy disk, a compact disk ROM (CD-ROM), a digital versatile disk (DVD), flash memory, a magneto-optical disk, or other types of nonvolatile machine-readable media that are capable of storing electronic data (e.g., including instructions). In an embodiment, components of the system 800 may be arranged in a point-to-point (PtP) configuration. For example, processors, memory, and/or input/output devices may be interconnected by a number of point-to-point interfaces.

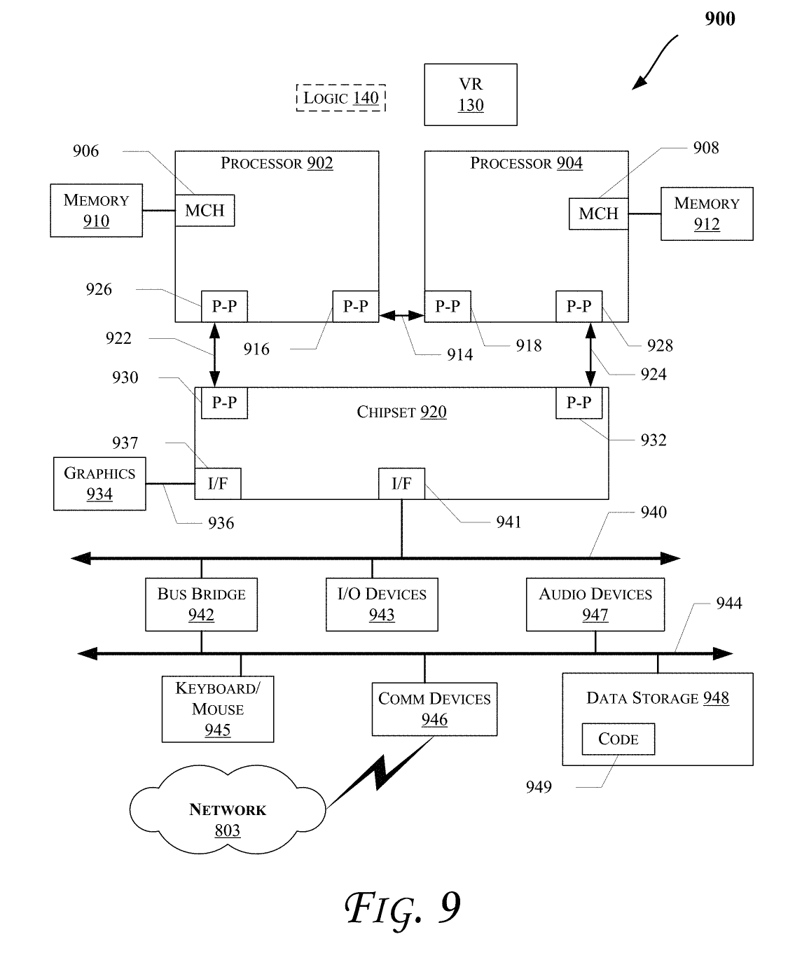

FIG. 9 illustrates a computing system 900 that is arranged in a point-to-point (PtP) configuration, according to an embodiment. In particular, FIG. 9 shows a system where processors, memory, and input/output devices are interconnected by a number of point-to-point interfaces. The operations discussed with reference to FIGS. 1-8 may be performed by one or more components of the system 900. For example, a voltage regulator (such as VR 130 of FIG. 1) may regulate voltage supplied to one or more components of FIG. 9 in conjunction with logic 140.

As illustrated in FIG. 9, the system 900 may include several processors, of which only two, processors 902 and 904 are shown for clarity. The processors 902 and 904 may each include a local memory controller hub (MCH) 906 and 908 to enable communication with memories 910 and 912. The memories 910 and/or 912 may store various data such as those discussed with reference to the memory 812 of FIG. 8. Also, the processors 902 and 904 may include one or more of the cores 106, logic 140, and/or VR 130 of FIG. 1.

In an embodiment, the processors 902 and 904 may be one of the processors 802 discussed with reference to FIG. 8. The processors 902 and 904 may exchange data via a point-to-point (PtP) interface 914 using PtP interface circuits 916 and 918, respectively. Also, the processors 902 and 904 may each exchange data with a chipset 920 via individual PtP interfaces 922 and 924 using point-to-point interface circuits 926, 928, 930, and 932. The chipset 920 may further exchange data with a high-performance graphics circuit 934 via a high-performance graphics interface 936, e.g., using a PtP interface circuit 937.

In at least one embodiment, one or more operations discussed with reference to FIGS. 1-9 may be performed by the processors 902 or 904 and/or other components of the system 900 such as those communicating via a bus 940. Other embodiments, however, may exist in other circuits, logic units, or devices within the system 900 of FIG. 9. Furthermore, some embodiments may be distributed throughout several circuits, logic units, or devices illustrated in FIG. 9.

Chipset 920 may communicate with the bus 940 using a PtP interface circuit 941. The bus 940 may have one or more devices that communicate with it, such as a bus bridge 942 and I/O devices 943. Via a bus 944, the bus bridge 942 may communicate with other devices such as a keyboard/mouse 945, communication devices 946 (such as modems, network interface devices, or other communication devices that may communicate with the computer network 803), audio I/O device, and/or a data storage device 948. The data storage device 948 may store code 949 that may be executed by the processors 902 and/or 904.

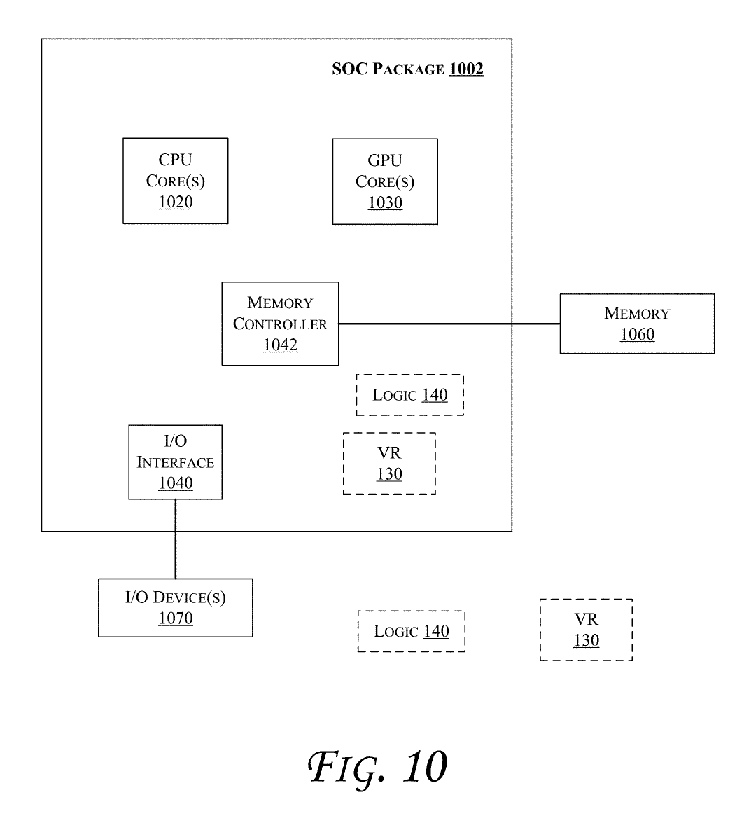

In some embodiments, one or more of the components discussed herein can be embodied as a System On Chip (SOC) device. FIG. 10 illustrates a block diagram of an SOC package in accordance with an embodiment. As illustrated in FIG. 10, SOC 1002 includes one or more Central Processing Unit (CPU) cores 1020, one or more Graphics Processor Unit (GPU) cores 1030, an Input/Output (I/O) interface 1040, and a memory controller 1042. Various components of the SOC package 1002 may be coupled to an interconnect or bus such as discussed herein with reference to the other figures. Also, the SOC package 1002 may include more or less components, such as those discussed herein with reference to the other figures. Further, each component of the SOC package 1020 may include one or more other components, e.g., as discussed with reference to the other figures herein. In one embodiment, SOC package 1002 (and its components) is provided on one or more Integrated Circuit (IC) die, e.g., which are packaged into a single semiconductor device.

As illustrated in FIG. 10, SOC package 1002 is coupled to a memory 1060 (which may be similar to or the same as memory discussed herein with reference to the other figures) via the memory controller 1042. In an embodiment, the memory 1060 (or a portion of it) can be integrated on the SOC package 1002.

The I/O interface 1040 may be coupled to one or more I/O devices 1070, e.g., via an interconnect and/or bus such as discussed herein with reference to other figures. I/O device(s) 1070 may include one or more of a keyboard, a mouse, a touchpad, a display, an image/video capture device (such as a camera or camcorder/video recorder), a touch screen, a speaker, or the like. Furthermore, SOC package 1002 may include/integrate the logic 140 and/or VR 130 in an embodiment. Alternatively, the logic 140 and/or VR 130 may be provided outside of the SOC package 1002 (i.e., as a discrete logic).

The following examples pertain to further embodiments. Example 1 may optionally include an apparatus comprising: a capacitor coupled to voltage regulator logic, wherein the capacitor is to provide substrate decoupling for a plurality of loads and wherein the capacitor is to decouple two or more voltage domains. Example 2 may optionally include the apparatus of example 1, wherein the capacitor is to provide decoupling for two or more power rails in a three or higher terminal configuration. Example 3 may optionally include the apparatus of example 1, wherein the capacitor is to decouple the two or more voltage domains corresponding to one or more substrates of a semiconductor package. Example 4 may optionally include the apparatus of example 1, wherein the capacitor is to decouple the two or more voltage domains by reassigning or splitting metallization plates inside a Multilayer Ceramic Capacitor (MLCC) construction. Example 5 may optionally include the apparatus of example 1, wherein the capacitor is a single physical structure with two decoupling capacitors and two series isolation inductors having the same or different nominal DC (Direct Current) voltage for lower cross-coupling noise between two different loads through inductive isolation. Example 6 may optionally include the apparatus of example 1, wherein the capacitor has a single physical structure with two decoupling capacitors having the same or different DC (Direct Current) voltage with series inductors with negative or positive coupling between the series inductors for lower cross-noise or self-noise between two different loads. Example 7 may optionally include the apparatus of example 1, wherein the capacitor is to obviate SRO (Solder Resist Opening) spacing for independent decoupling. Example 8 may optionally include the apparatus of example 1, wherein the two or more voltage domains are to be coupled to a single circuit. Example 9 may optionally include the apparatus of example 1, wherein the capacitor is to comprise a capacitor on a semiconductor package or on a motherboard. Example 10 may optionally include the apparatus of example 1, wherein the capacitor is a separate component on an integrated circuit die or on a load side. Example 11 may optionally include the apparatus of example 1, wherein the capacitor is to be coupled between the voltage regulator logic and a power source. Example 12 may optionally include the apparatus of example 1, wherein the capacitor is to be coupled between the voltage regulator logic and a processor having one or more processor cores. Example 13 may optionally include the apparatus of example 1, wherein the voltage regulator logic is to comprise one or more of: a buck voltage regulator logic, a boost voltage regulator logic, switched capacitor voltage regulator, or combinations thereof. Example 14 may optionally include the apparatus of example 1, wherein the voltage regulator logic is to comprise a multi-phase voltage regulator logic. Example 15 may optionally include the apparatus of example 1, wherein one or more of: the voltage regulator logic, a processor having one or more processor cores, the capacitor, and memory are on a single integrated circuit.

Example 16 may optionally include a computing system comprising: memory to store data; a processor, coupled to the memory, to perform one or more operations on the stored data; and a capacitor coupled to voltage regulator logic, wherein the capacitor is to provide substrate decoupling for a plurality of loads and wherein the capacitor is to decouple two or more voltage domains. Example 17 may optionally include the system of example 16, wherein the capacitor is to provide decoupling for two or more power rails in a three or higher terminal configuration. Example 18 may optionally include the system of example 16, wherein the capacitor is to decouple the two or more voltage domains corresponding to one or more substrates of a semiconductor package. Example 19 may optionally include the system of example 16, wherein the capacitor is to decouple the two or more voltage domains by reassigning or splitting metallization plates inside a Multilayer Ceramic Capacitor (MLCC) construction. Example 20 may optionally include the system of example 16, wherein the capacitor has a single physical structure with two decoupling capacitors and two series inductors having the same or different nominal DC (Direct Current) voltage for lower cross-coupling noise between two different loads through common inductive isolation. Example 21 may optionally include the system of example 16, wherein the capacitor is a single physical structure with two decoupling capacitors having the same or different DC (Direct Current) voltage with series inductors with negative or positive coupling between the series inductors for lower cross-noise and self-noise between two different loads. Example 22 may optionally include the system of example 16, wherein the capacitor is to obviate SRO (Solder Resist Opening) spacing for independent decoupling. Example 23 may optionally include the system of example 16, wherein the two or more voltage domains are to be coupled to a single circuit. Example 24 may optionally include the system of example 16, wherein the capacitor is to comprise a capacitor on a semiconductor package or on a motherboard. Example 25 may optionally include the system of example 16, wherein the capacitor is a separate component on an integrated circuit die or on a load side.

Example 26 may optionally include an apparatus comprising means to perform a method as set forth in any preceding example.

In various embodiments, the operations discussed herein, e.g., with reference to FIGS. 1-10, may be implemented as hardware (e.g., logic circuitry), software, firmware, or combinations thereof, which may be provided as a computer program product, e.g., including a tangible machine-readable or computer-readable medium having stored thereon instructions (or software procedures) used to program a computer to perform a process discussed herein. The machine-readable medium may include a storage device such as those discussed with respect to FIGS. 1-10.

Additionally, such computer-readable media may be downloaded as a computer program product, wherein the program may be transferred from a remote computer (e.g., a server) to a requesting computer (e.g., a client) by way of data signals provided in a carrier wave or other propagation medium via a communication link (e.g., a bus, a modem, or a network connection).

Reference in the specification to “one embodiment” or “an embodiment” means that a particular feature, structure, and/or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus comprising:
a capacitor coupled to voltage regulator logic,
wherein the capacitor is to provide substrate decoupling for a plurality of loads and wherein the capacitor is to decouple two or more voltage domains.

2. The apparatus of claim 1, wherein the capacitor is to provide decoupling for two or more power rails in a three or higher terminal configuration.

3. The apparatus of claim 1, wherein the capacitor is to decouple the two or more voltage domains corresponding to one or more substrates of a semiconductor package.

4. The apparatus of claim 1, wherein the capacitor is to decouple the two or more voltage domains by reassigning or splitting metallization plates inside a Multilayer Ceramic Capacitor (MLCC) construction.

5. The apparatus of claim 1, wherein the capacitor is a single physical structure with two decoupling capacitors and two series isolation inductors having the same or different nominal DC (Direct Current) voltage for lower cross-coupling noise between two different loads through inductive isolation.

6. The apparatus of claim 1, wherein the capacitor has a single physical structure with two decoupling capacitors having the same or different DC (Direct Current) voltage with series inductors with negative or positive coupling between the series inductors for lower cross-noise or self-noise between two different loads.

7. The apparatus of claim 1, wherein the capacitor is to obviate SRO (Solder Resist Opening) spacing for independent decoupling.

8. The apparatus of claim 1, wherein the two or more voltage domains are to be coupled to a single circuit.

9. The apparatus of claim 1, wherein the capacitor is to comprise a capacitor on a semiconductor package or on a motherboard.

10. The apparatus of claim 1, wherein the capacitor is a separate component on an integrated circuit die or on a load side.

11. The apparatus of claim 1, wherein the capacitor is to be coupled between the voltage regulator logic and a power source.

12. The apparatus of claim 1, wherein the capacitor is to be coupled between the voltage regulator logic and a processor having one or more processor cores.

13. The apparatus of claim 1, wherein the voltage regulator logic is to comprise one or more of: a buck voltage regulator logic, a boost voltage regulator logic, switched capacitor voltage regulator, or combinations thereof.

14. The apparatus of claim 1, wherein the voltage regulator logic is to comprise a multi-phase voltage regulator logic.

15. The apparatus of claim 1, wherein one or more of: the voltage regulator logic, a processor having one or more processor cores, the capacitor, and memory are on a single integrated circuit.

16. A computing system comprising:
memory to store data;
a processor, coupled to the memory, to perform one or more operations on the stored data; and
a capacitor coupled to voltage regulator logic,
wherein the capacitor is to provide substrate decoupling for a plurality of loads and wherein the capacitor is to decouple two or more voltage domains.

17. The system of claim 16, wherein the capacitor is to provide decoupling for two or more power rails in a three or higher terminal configuration.

18. The system of claim 16, wherein the capacitor is to decouple the two or more voltage domains corresponding to one or more substrates of a semiconductor package.

19. The system of claim 16, wherein the capacitor is to decouple the two or more voltage domains by reassigning or splitting metallization plates inside a Multilayer Ceramic Capacitor (MLCC) construction.

20. The system of claim 16, wherein the capacitor has a single physical structure with two decoupling capacitors and two series inductors having the same or different nominal DC (Direct Current) voltage for lower cross-coupling noise between two different loads through common inductive isolation.

21. The system of claim 16, wherein the capacitor is a single physical structure with two decoupling capacitors having the same or different DC (Direct Current) voltage with series inductors with negative or positive coupling between the series inductors for lower cross-noise and self-noise between two different loads.

22. The system of claim 16, wherein the capacitor is to obviate SRO (Solder Resist Opening) spacing for independent decoupling.

23. The system of claim 16, wherein the two or more voltage domains are to be coupled to a single circuit.

24. The system of claim 16, wherein the capacitor is to comprise a capacitor on a semiconductor package or on a motherboard.

25. The system of claim 16, wherein the capacitor is a separate component on an integrated circuit die or on a load side.
